(19) United States
(12) Patent Application Publication
(10) Pub. No.: US 2010/0109957 A1
(43) Pub. Date: May 6, 2010

(54) APPARATUS FOR MEASURING ANTENNA RADIATION PERFORMANCE AND METHOD OF DESIGNING THE SAME

(75) Inventors: Jung-Ick MOON, Daejon (KR); Soon-Soo OH, Daejon (KR); Joung-Myoun KIM, Daejon (KR); Soon-Ik JEON, Daejon (KR); Chang-Joo KIM, Daejon (KR)

Correspondence Address: Jae Y. Park, Kile, Goekjian, Reed & McManus, PLLC, 1200 New Hampshire Ave. NW, Suite 570, Washington, DC, 20036, US

(73) Assignee: Electronics and Telecommunications Research Institute, Daejon (KR)

(21) Appl. No.: 12/610,524

(22) Filed: Nov. 2, 2009

(30) Foreign Application Priority Data
Nov. 4, 2008 (KR) 10-2008-0109013

(51) Int. Cl. G01R 29/08; G06F 17/50

(52) U.S. Cl. 343/703; 703/1

(57) ABSTRACT

Provided are an antenna radiation performance measuring apparatus and a method for designing the same. The apparatus includes a chamber configured to include a transmit antenna radiating electromagnetic wave, a receive antenna receiving the electromagnetic wave, and an electromagnetic wave absorber absorbing the electromagnetic wave, and a reflector disposed on one side of the chamber between the transmit antenna and the receive antenna, inclined at a predetermined angle, and configured to reflect an electromagnetic wave radiated in a direction to the one side from the transmit antenna.

### CROSS-REFERENCE TO RELATED APPLICATIONS

The present invention claims priority of Korean Patent Application No. 10-2008-0109013, filed on Nov. 4, 2008, which is incorporated herein by reference.

### BACKGROUND OF THE INVENTION

1. Field of the Invention

The present invention relates to an apparatus for measuring antenna radiation performance and a method of designing the same and, more particularly, to an apparatus for measuring radiation performance including a radiation pattern and a gain of an antenna and a method of designing the same.

2. Description of Related Art

In general, a wireless communication system transmits or receives a signal and data using a predetermined frequency. The wireless communication system includes an antenna as an essential element for transmitting and receiving a signal. The antenna needs to be designed to effectively transmit and receive an electromagnetic wave. Many researchers have been proposed various designs for an antenna to effectively transmit and receive an electromagnetic wave.

An antenna has properties changing according to a material and a shape thereof. Therefore, it is very important to accurately analyze the antenna properties. After designing an antenna with a predetermined material and shape, it is required to actually measure antenna properties thereof as well as theoretical verification.

Hereinafter, a method for measuring antenna radiation performance according to the prior art will be described.

Generally, a method of measuring antenna radiation performance may be classified into two methods. As a first method, a fully-anechoic chamber with an electromagnetic wave absorber attached is used to measure the antenna radiation performance. The specifications of an electromagnetic wave absorber attached on interior walls of the fully-anechoic chamber are decided according to a radiation frequency of an antenna. The lower the radiation frequency of an antenna is, the longer the wavelength of the radiation frequency of an antenna becomes. That is, a size or a volume of the electromagnetic wave absorber must be enlarged in proportion to a wavelength.

For example, a fully-anechoic chamber for measuring 200 MHz is required to have a sufficient space to dispose a transmit antenna and a receive antenna with a distance longer than 15 m. Also, an electromagnetic wave absorber is required to have a thickness of 1.5 m. The performance of the fully-anechoic member is decided by error of electric field uniformity in the quiet zone. Allowable error of the electric field uniformity in the quiet zone is about 0.25 dB and 22.5 degrees. Therefore, a fully-anechoic chamber for measuring a property of an antenna for a low radiation frequency requires a large space and a high cost to build.

As a second method, a semi-anechoic chamber is used to measure the radiation performance of an antenna. The semi-anechoic chamber is designed to easily absorb a low frequency band electric wave except a metal floor thereof. The method of measuring antenna radiation performance using a semi-anechoic chamber will be described with reference to FIG. 1.

FIG. 1 is a vertical cross-sectional view of a semi-anechoic chamber according to the prior art.

As shown in FIG. 1, the semi-anechoic chamber 10 according to the prior art includes a hexahedron interior space. The semi-anechoic chamber 10 includes a metal floor 12. Electromagnetic wave absorbers 14 are attached on side walls and a ceiling except the metal floor 12. A transmit antenna 20 and a receive antenna 30 are disposed with a height D from the metal floor 12 as shown in FIG. 1. The transmit antenna 20 and the receive antenna 30 are separated at a distance R. The distance R is decided according to a frequency or an antenna property. The receive antenna 30 is disposed on a rotator 42. The rotator 42 rotates the receive antenna 30 on an x-z plane with a predetermined angular speed step. A vector network analyzer 50 supplies an electric signal to the transmit antenna 20 and receives an electric signal corresponding to an electromagnetic wave received at the receive antenna 30. A data processor 52 calculates a radiation pattern and a gain of the receive antenna 30 based on the supplied electric signal from the vector network analyzer 50 and the received electric signal. A controller 54 controls the rotation of the rotator 42. The data processor 52 also applies a control signal for rotating the rotator 42.

In case of measuring the radiation characteristics of the receive antenna 30, the transmit antenna 20 outputs a signal having a predetermined frequency. Here, the transmit antenna 20 radiates electromagnetic waves in various directions. For example, FIG. 1 shows the transmit antenna 20 radiating first to fourth electromagnetic waves 22, 23, 24, and 26 in various directions.

The first electromagnetic wave 22 propagates toward the receive antenna 30 in parallel to the metal floor 12. The second, third, and fourth electromagnetic waves 23, 24, and 26 propagate toward the metal floor 12 or the ceiling. Such second, third, and fourth electromagnetic waves 23, 24, and 26 may cause error when the radiation performance of the receive antenna 30 is measured. Therefore, the electromagnetic wave absorbers 14 are attached on the sidewalls and the ceiling of the semi-anechoic chamber 10 except the metal floor. That is, the second electromagnetic wave 23 propagating toward the ceiling does not inference the measurement of the radiation performance because it is absorbed by the electromagnetic wave absorber 14 attached on the ceiling of the semi-anechoic chamber 10.

On the contrary, the third electromagnetic wave 24 and the fourth electromagnetic wave 26 propagating toward the metal floor 12 are reflected to the metal floor 12. Such the reflected electromagnetic waves 25 and 27 of the third and fourth electromagnetic waves 24 and 26 act as interference to the first electromagnetic wave 22. As described above, it is difficult to form a uniform electric field at the receive antenna 30 in the semi-anechoic chamber 10. That is, non-uniform electric field makes it difficult to accurately measure the radiation performance of the receive antenna 30.

Therefore, the semi-anechoic chamber 10 has been used only for measuring an effective radiated power (ERP) or for measuring interference of an electromagnetic wave radiated from the transmit antenna 20.

### SUMMARY OF THE INVENTION

An embodiment of the present invention is directed to providing an antenna radiation performance measuring apparatus for making an electromagnetic wave radiated from an antenna to form a uniform electric field, and a method for designing the same.

Another embodiment of the present invention is directed to providing an antenna radiation performance measuring apparatus for accurately measuring radiation performance of an antenna using a low frequency band including a VHF band (174 to 216 MHz).

In accordance with an aspect of the present invention, there is provided an apparatus for measuring an antenna radiation performance including a chamber configured to include a transmit antenna radiating electromagnetic wave, a receive antenna receiving the electromagnetic wave, and an electromagnetic wave absorber absorbing the electromagnetic wave, and a reflector disposed on one side of the chamber between the transmit antenna and the receive antenna, inclined at a predetermined angle, and configured to reflect an electromagnetic wave radiated in a direction to the one side from the transmit antenna.

In accordance with another aspect of the present invention, there is provided a method for designing an antenna radiation performance measuring apparatus including a chamber configured to have a transmit antenna radiating electromagnetic wave, a receive antenna receiving the electromagnetic wave, and an electromagnetic wave absorber absorbing the electromagnetic wave, and a reflector disposed on one side of the chamber between the transmit antenna and the receive antenna, inclined at a predetermined angle, and configured to reflect an electromagnetic wave radiated from the transmit antenna, the method including deciding parameters according to locations of the transmit antenna and the receive antenna in the chamber, measuring an angle and a location of the reflector based on the decided parameters, confirming performance of uniformity of electric field of an electromagnetic wave received at the receive antenna within the quiet zone, and measuring a radiation pattern and a gain of the receive antenna.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

### BRIEF DESCRIPTION OF THE DRAWINGS

FIG. 1 is a vertical cross-sectional view of a semi-anechoic chamber according to the prior art.

FIG. 2 is a vertical cross-sectional view of an antenna radiation performance measuring apparatus in accordance with an embodiment of the present invention.

FIG. 3 is a flowchart describing a method for designing an antenna radiation performance measuring apparatus in accordance with an embodiment of the present invention.

FIGS. 4A and 4B are graphs showing normalized amplitude and a phase of a measured electric field formed in a typical fully-anechoic chamber.

FIGS. 5A and 5B are graphs showing normalized amplitude and a phase of a measured electric field formed in a typical semi-anechoic chamber.

FIGS. 6A and 6B are graphs showing normalized amplitude and a phase of a measured electric field formed in an antenna radiation performance measurement apparatus according to the present embodiment.

FIGS. 7A and 7B are graphs showing normalized amplitudes and phases of electric field formed in a fully-anechoic chamber.

FIGS. 8A and 8B are graphs showing normalized amplitudes and phases of electric field formed in a semi-anechoic chamber.

FIGS. 9A and 9B are graphs showing normalized amplitudes and phases of electric field formed in an antenna radiation performance measuring apparatus.

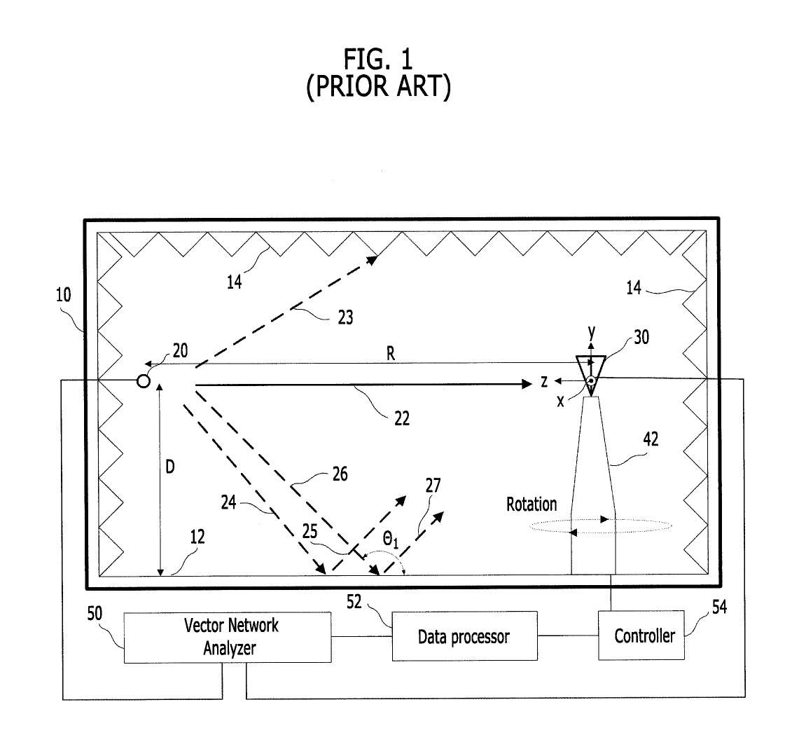

### DESCRIPTION OF SPECIFIC EMBODIMENTS

The advantages, features and aspects of the invention will become apparent from the following description of the embodiments with reference to the accompanying drawings, which is set forth hereinafter.

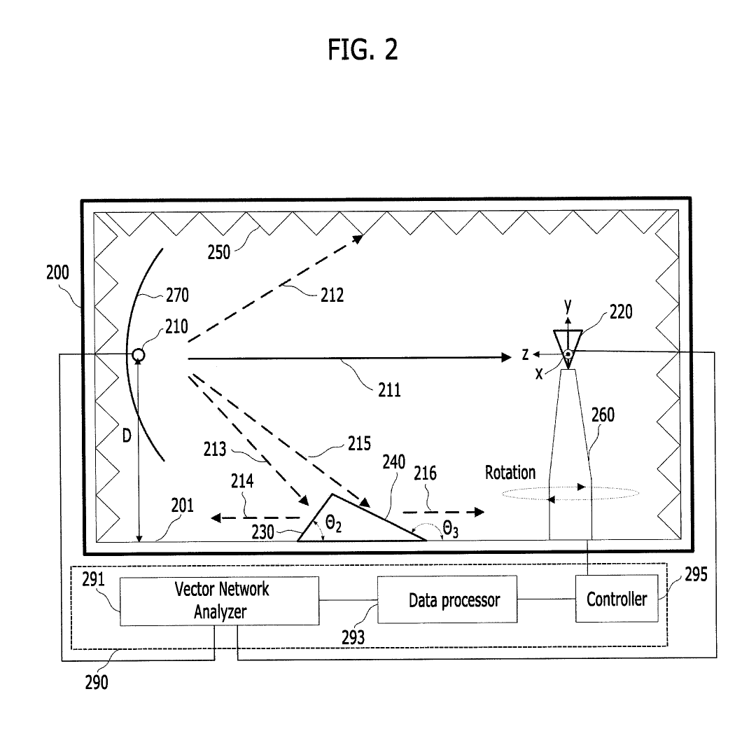

FIG. 2 is a vertical cross-sectional view of an antenna radiation performance measuring apparatus in accordance with an embodiment of the present invention.

Referring to FIG. 2, the antenna radiation performance measuring apparatus according to the present embodiment includes a chamber 200, a transmit antenna 210, a receive antenna 220, reflectors 230 and 240, and electromagnetic wave absorber 250. In FIG. 2, an x-axis, a y-axis, and a z-axis are shown with the receive antenna 220 as origin for convenience. The x-axis, the y-axis, and the z-axis form 90 degrees to each other, and the z-axis is parallel with the floor 201.

The chamber 200 provides a space designed to measuring the radiation performance of the receive antenna 220. As shown in FIG. 2, the chamber 200 is formed in a rectangular shape in a 2-D plane or in a hexahedron shape in a 3-D plane. However, the present invention is not limited thereto. The chamber may be formed in various shapes such as polyhedral structure including an ellipsoid shape and a sphere shape. The chamber 200 includes a metal floor 201. Except the metal floor 201, the electromagnetic wave absorber 250 is attached on sidewalls and ceiling of the chamber 200.

The transmit antenna 210 radiates electromagnetic waves having a predetermined frequency. The transmit antenna 210 is disposed in the chamber 200 at a predetermined height D from the metal floor 201.

The receive antenna 220 receives an electromagnetic wave radiated from the transmit antenna 210. It is preferable to dispose the receive antenna 220 in the chamber 200 at the same height D from the metal floor.

The reflectors 230 and 240 are disposed between the transmit antenna 210 and the receive antenna 220 on the metal floor 201. The reflectors 230 and 240 are inclined at a predetermined angle from the metal floor 201. Although the antenna radiation performance measuring apparatus according to the present embodiment is described to include two reflectors 230 and 240, the present invention is not limited thereto. The antenna radiation performance measuring apparatus according to another embodiment of the present invention may include only one of two reflectors 230 and 240. The locations of the first and second reflectors will be described in later.

In Eq. 1, R denotes a distance between the transmission antenna 210 and the receive antenna 220, and D denotes a height of the transmission antenna 210 and the receive antenna 220 from the metal floor 201. θ₁ indicates an angle between the metal floor 201 and an electromagnetic wave entering at a location R/2 on the metal floor 201. The unit of the angle θ₁ is a degree “°”.

The first reflector 230 forms an angle θ₂ from the metal floor 230. The angle θ₂ is approximated by Eq. 1.

$$\begin{matrix}{θ}_{1} = 90 ° + {tan}^{- 1} ( \frac{R}{2 D} ) & Eq . 1 \\ {θ}_{2} = \frac{{θ}_{1}}{2} & Eq . 2\end{matrix}$$

The first reflector 230 reflects the electromagnetic wave 213 propagating toward the metal floor 201 from the transmit antenna 210 in a positive z direction. The reflected wave 214 is absorbed by the electromagnetic wave absorber 250 attached at the interior wall of the chamber 200.

The second reflector 240 forms an angle θ₃ from the metal floor 230 and forms an angle (180°−θ₃) in a direction to the transmit antenna 210. The angle θ₃ is approximated by Eq. 2.

$${θ}_{3} = \frac{{θ}_{1}}{2} + 90 ° \qquad Eq . 3$$

In Eq. 3, the angle θ₁ is identical to the angle θ₁ in Eq. 1. The unit of the angle θ₃ is a degree)(°).

The second reflector 240 reflects the electromagnetic wave 215 propagating from the transmit antenna 210 toward the metal floor 201 in a negative z direction. The reflected wave 216 of the electromagnetic wave 215 passes through a rotator 260 formed of low reflective material and is absorbed by the electromagnetic wave absorber 250 attached at the interior walls of the chamber 200.

The antenna radiation performance measuring apparatus according to the present embodiment can form a uniform electric field in a measurement area of the receive antenna 220 because the reflected waves 214 and 216 transferred to the receive antenna 220 propagate in parallel with the metal floor 201. Also, it is possible to measure the radiation pattern and the gain of the receive antenna 220 operating in a frequency band lower than a VHF band identically to the fully-anechoic chamber. Further, the antenna radiation performance measuring apparatus according to the present embodiment may be applied to measure the radiation performance of the receive antenna 220 for a frequency lower than a low limit frequency of a fully-anechoic chamber. Particularly, the antenna radiation performance measuring apparatus according to the present embodiment provide the effect of obtaining a direct wave in a semi-anechoic chamber where many reflected waves are generated. Furthermore, the utilization of the semi-anechoic chamber can be improved in views of time and cost.

Meanwhile, the antenna radiation performance measuring apparatus according to the present embodiment further includes a reflective plate 270.

The reflective plate 270 is disposed around the transmit antenna 210 for concentrating the electromagnetic waves to the location of the receive antenna 220. The reflective plate 270 further improves the directivity of the transmit antenna 210.

The receive antenna 220 is disposed on the rotator 260. The rotator 260 rotates the receive antenna 220 in parallel with an x-z plane and is formed of a less reflective material.

An antenna radiation performance measuring system 290 includes a vector network analyzer 291, a data processor 293, and a controller 295.

The vector network analyzer 291 applies an electric signal to the transmit antenna 210 and receives an electric signal corresponding to an electromagnetic waves received at the receive antenna 220.

The data processor 293 calculates the radiation pattern and the gain of the receive antenna 220 based on the electric signal from the vector network analyzer 291 and the received electric signal. The data processor 293 transmits the calculated radiation performance of the receive antenna 220 to a user interface (not shown) to show the radiation performance of the receive antenna 220 to a user. The data processor 293 receives a signal from a user for rotating the rotator 260 at a predetermined angle and generates a corresponding control signal thereof.

The controller 295 controls the rotation of the rotator 260. The controller 295 receives a control signal from the data processor 293 to rotate the rotator 260.

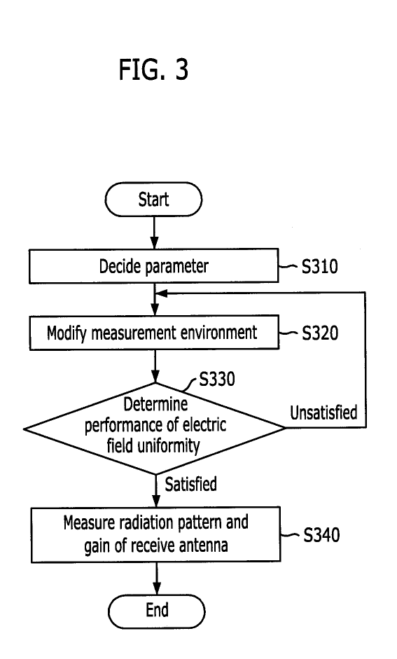

FIG. 3 is a flowchart describing a method for designing an antenna radiation performance measuring apparatus in accordance with an embodiment of the present invention.

Referring to FIG. 3, measurement environment parameters and an angle θ₁ are decided at step S310. The measurement environment parameters includes a distance R between the transmit antenna 310 and the receive antenna 220 and target frequency bands such as a lower limit frequency f1 and an upper limit frequency f2. Eq. 1 is used to decide the angle θ₁.

At step S320, the measurement environment of the antenna radiation performance measurement apparatus is modified. That is, the reflective plate 270 in the behind of the transmit antenna 210 and the reflectors 230 and 240 on the metal floor 201 are designed. The reflective plate 270 is designed by describing a parabola at the center of the transmit antenna 210 in consideration of the size of the chamber 200. The center of the reflective plate 270 is controlled by shifting the center in parallel with a z-axis based on the directivity of each frequency band. The angles of the reflectors 230 and 240 are designed using Eq. 2 and Eq. 3. The reflectors 230 and 240 may be disposed at about a location of R/2.

At step S330, the uniformity of electric field is measured at a measurement area of an electromagnetic wave radiated from the transmit antenna 210 to determine whether the receive antenna has target specifications that a user wants. If it is not satisfied, the step S320 is performed again. At step S320, the uniformity of the electric field is re-measured after tilting the reflective plate 270 to up and down directions based on the center of the transmit antenna 210. Or, the electric field uniformity is re-measured after moving the reflectors 230 and 240 in parallel with a z-axis.

When the electric field uniformity is satisfied in the target specifications of a user, the receive antenna 220 is installed and the radiation performance of the receive antenna 220 is measured by each angle at step S340.

As described above, the method of designing an antenna radiation performance measurement apparatus according to the present enables designing an antenna radiation performance measurement apparatus to make an electromagnetic wave radiated from the transmit antenna 210 to form uniform electric field.

Also, the method of designing an antenna radiation performance measuring apparatus according to the present embodiment enables designing an antenna radiation performance measurement apparatus to accurately measure the radiation performance of a receive antenna using a low frequency band including a VHF band 174 to 216 MHz.

Hereinafter, the uniformity of electric fields measured by an antenna radiation performance measurement apparatus according to the present embodiment will be compared with those measured in a fully-anechoic chamber and in a semi-anechoic chamber according to the prior art.

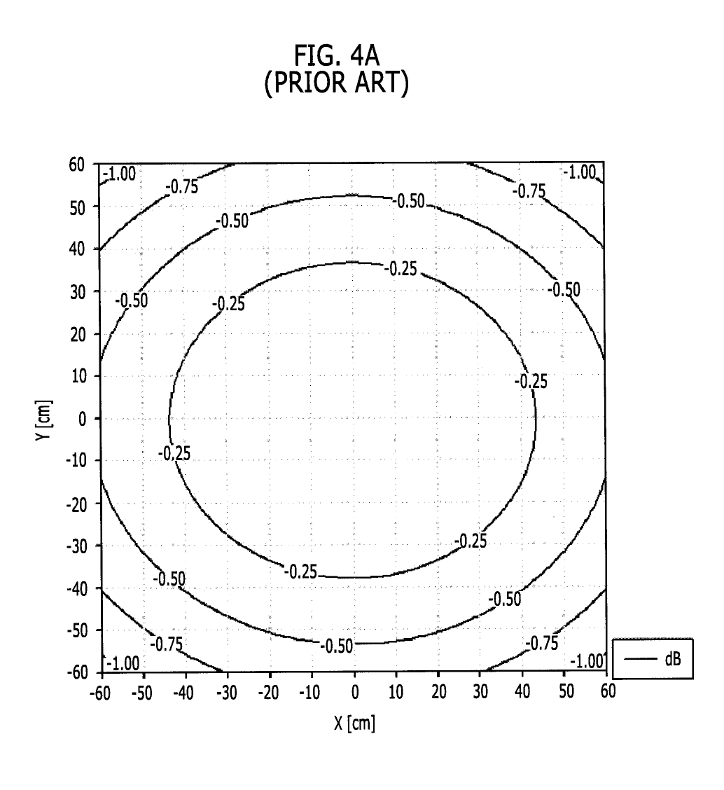

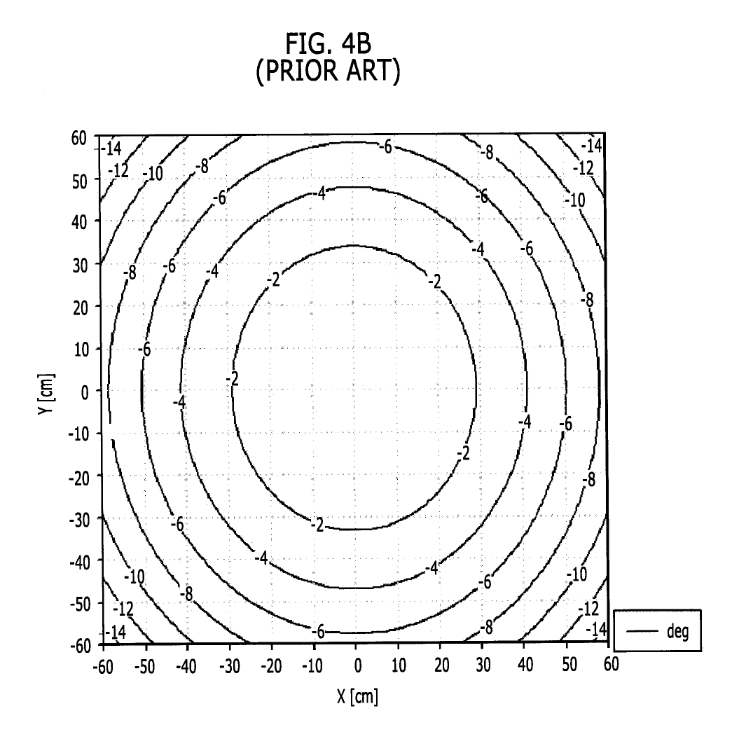

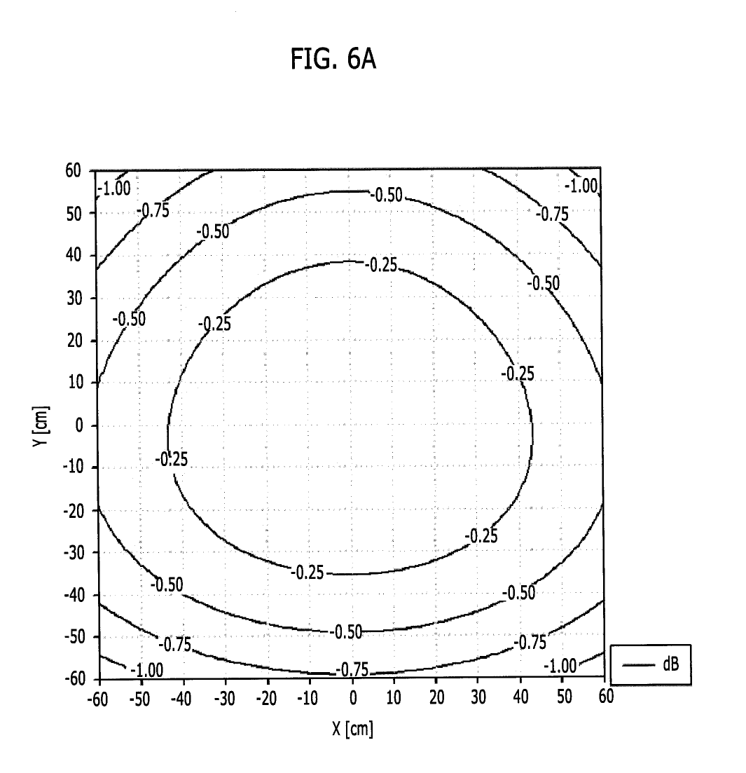

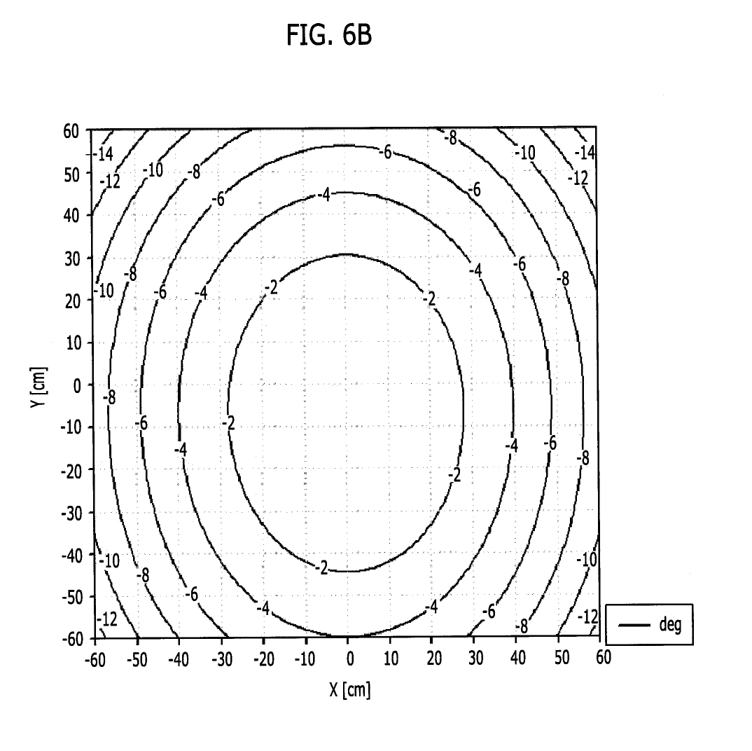

Referring to FIGS. 4 and 6, when the electromagnetic wave radiated from the transmit antenna is a lower limit frequency f1, the uniformity of electric field will be described. The measurement area of the electric field is shown on an x-y plane with a receive antenna as an origin.

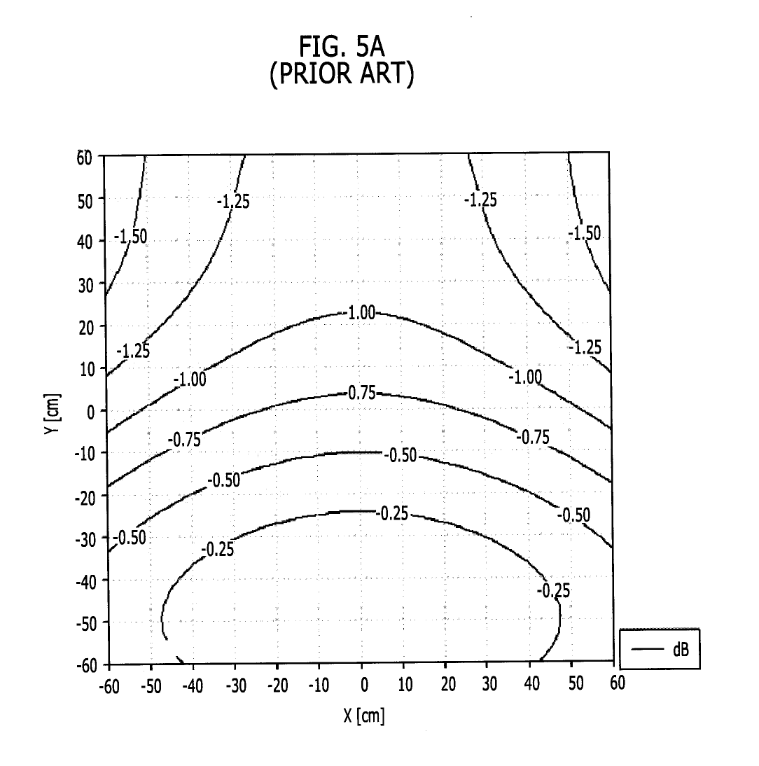

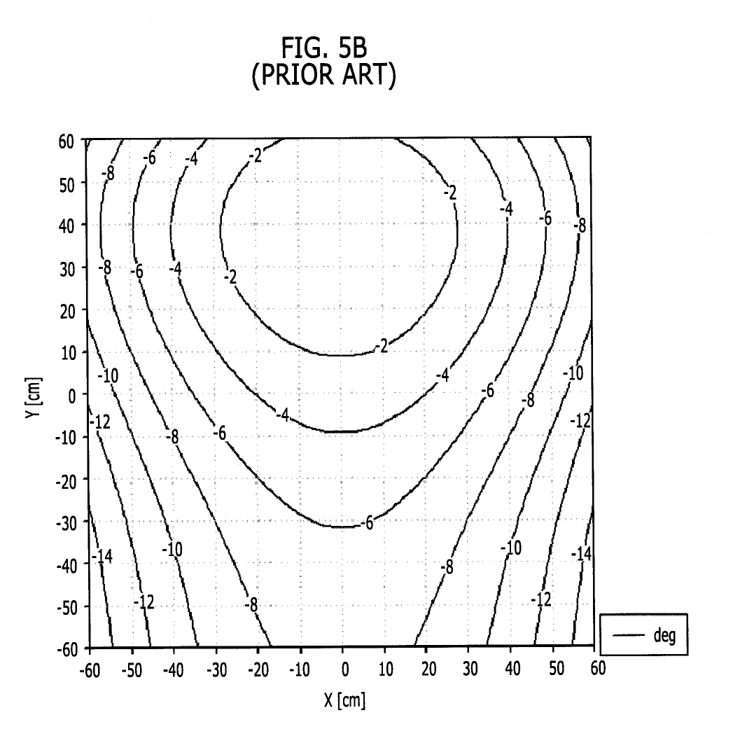

FIGS. 4A and 4B are graphs showing normalized amplitude and a phase of a measured electric field formed in a typical fully-anechoic chamber. FIGS. 5A and 5B are graphs showing normalized amplitude and a phase of a measured electric field formed in a typical semi-anechoic chamber. FIGS. 6A and 6B are graphs showing normalized amplitude and a phase of a measured electric field formed in an antenna radiation performance measurement apparatus according to the present embodiment. Since a permissible error of the electric field uniformity is about 0.25 dB and 22.5 deg from the center, the measurable size of an antenna is about 70 cm in FIGS. 4 to 6.

The graphs of FIGS. 4A and 4B show that a normalized amplitudes and phases of an isotropic electric field are distributed based on an origin (x=0, y=0). The graphs of FIGS. 5A and 5B show that the maximum values of the normalized amplitudes and phase |[a1]s of the electric field are shifted from the center due to the reflected lights. The graphs of FIGS. 5A and 5B also show that the graph does not have isotropic distribution. The graphs of FIGS. 6A and 6B show that the graphs have the isotropic distribution of normalized amplitudes and a phase |[a2]s of the electric field based on the origin (x=0, y=0) like the graphs of FIGS. 4A and 4B. As shown, the antenna radiation performance measurement apparatus according to the present embodiment can provide an excellent measurement area because the maximum value is located at the origin and the amplitude and the phase of the electric field are isotropic-distributed although the measuring result of the antenna radiation performance measuring apparatus according to the present embodiment is not identically to the ideal measuring result of the fully-anechoic chamber of FIG. 4.

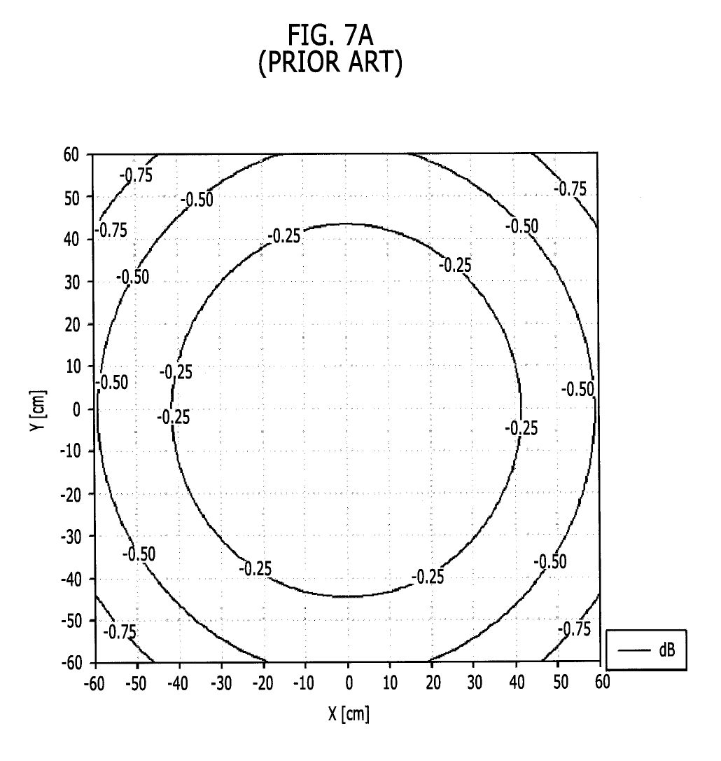

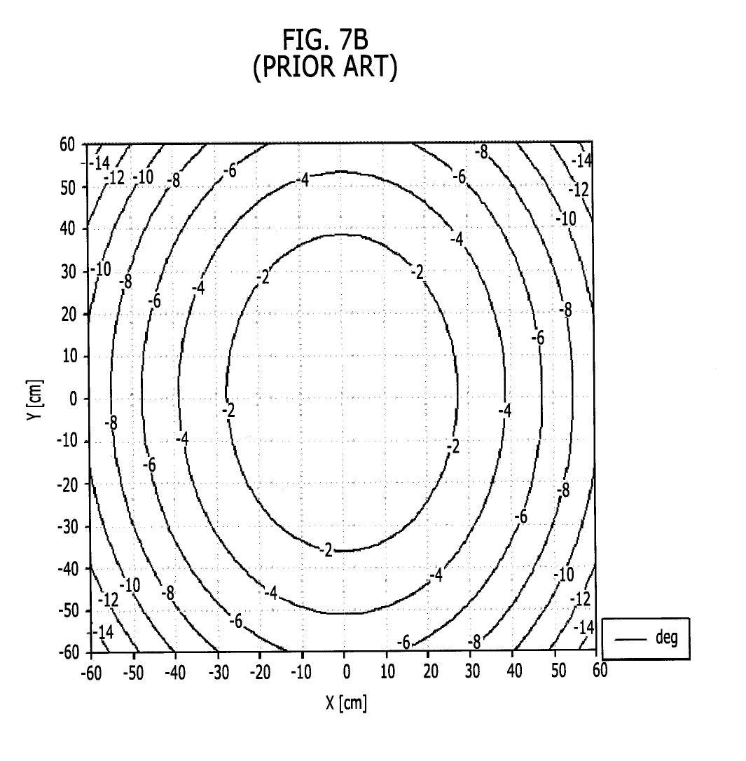

Referring to FIGS. 7 to 9, the uniformity of electric field formed when the transmit antenna radiates an electromagnetic wave having an upper limit frequency f2 will be described. Here, the measurement area of electric field is an x-y plane with a receive antenna as an origin.

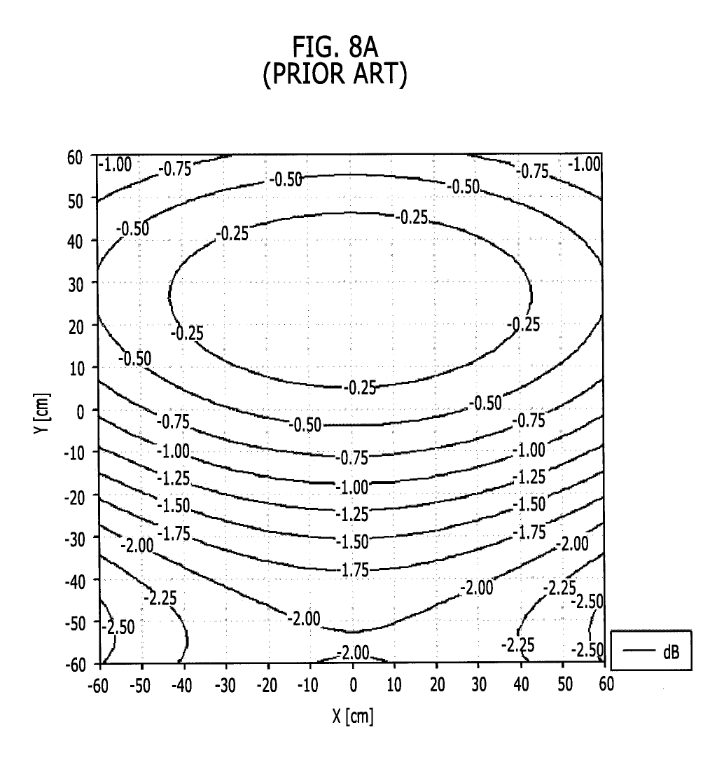

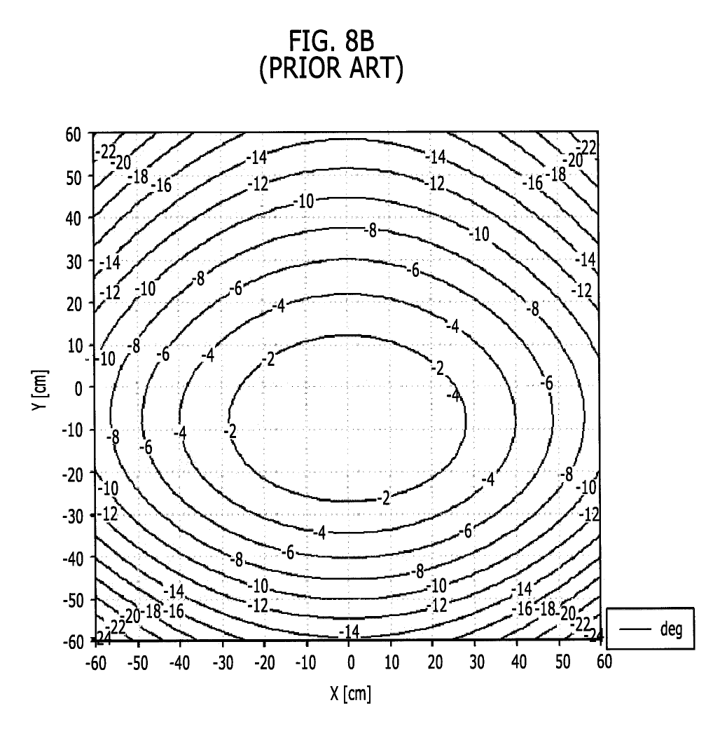

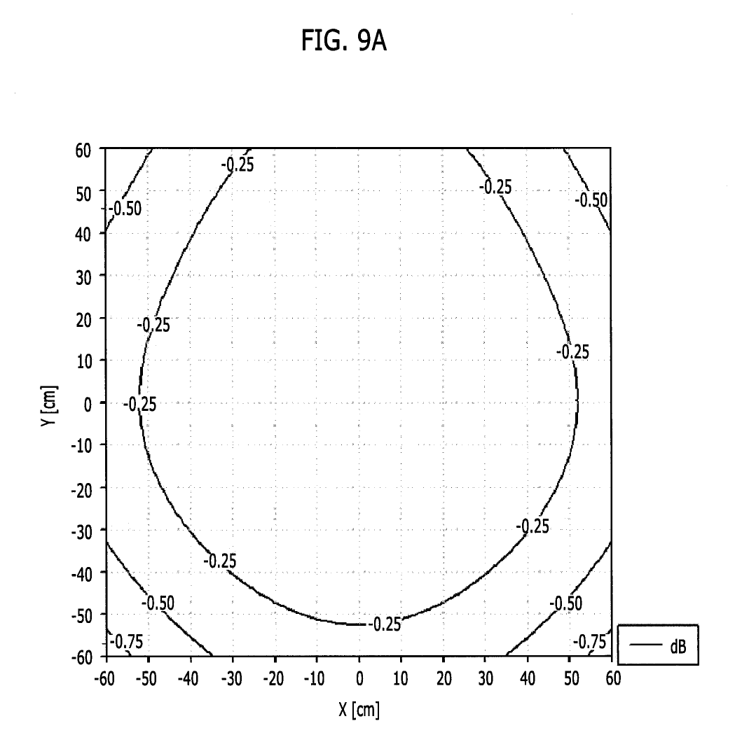

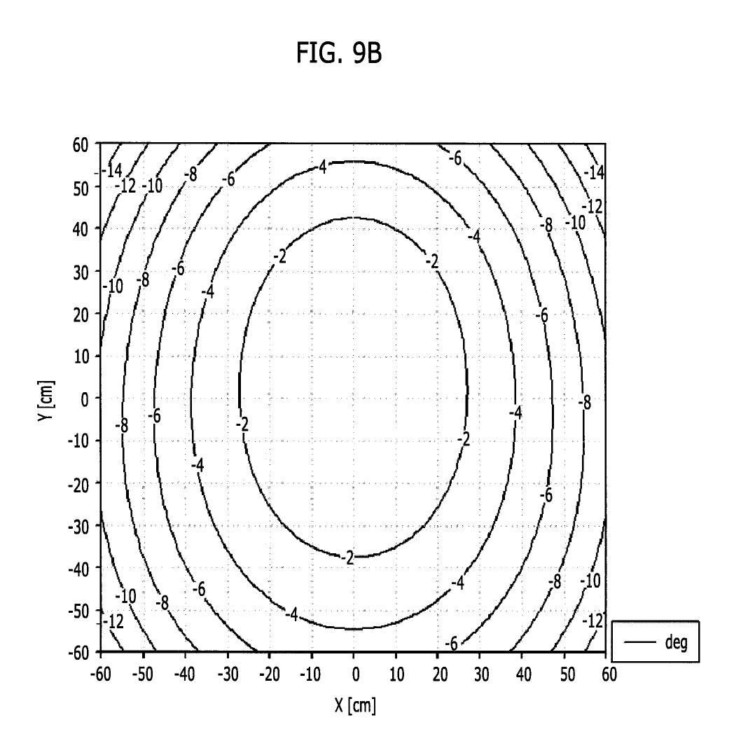

FIGS. 7A and 7B are graphs showing amplitudes and phases of electric field formed in a fully-anechoic chamber. FIGS. 8A and 8B are graphs showing amplitudes and phases of electric field formed in a semi-anechoic chamber. FIGS. 9A and 9B are graphs showing amplitudes and phases of electric field formed in an antenna radiation performance measuring apparatus. Since an allowable error of an antenna is about 0.25 dB and 22.5 deg from the center of the antenna, the measurement size is about 80 cm in FIGS. 7 to 9.

As shown in FIGS. 7 to 9, the antenna radiation performance measurement apparatus according to the present embodiment can provide an excellent measurement area because the maximum value is located at the origin and the amplitude and the phase of the electric field are isotropic-distributed although the measuring result of the antenna radiation performance measuring apparatus according to the present embodiment is not identically to the ideal measuring result of the fully-anechoic chamber of FIG. 5.

As described above, the antenna radiation measurement apparatus according to the present invention makes the electromagnetic wave radiated from the transmit antenna to form a uniform electric field. Accordingly, it is possible to accurately measure the radiation performance of an antenna using a low frequency band including VHF band (174 to 216 MHz).

The method for designing an antenna radiation performance measurement apparatus according to the present embodiment can design an antenna radiation performance measurement apparatus to make the electromagnetic wave radiated from the transmit antenna to form uniform electric field. It is possible to design an antenna radiation performance measuring apparatus to accurately measure the radiation performance of an antenna using a low frequency band such as VHF band (174 to 216 MHz).

While the present invention has been described with respect to the specific embodiments, it will be apparent to those skilled in the art that various changes and modifications may be made without departing from the spirit and scope of the invention as defined in the following claims.

What is claimed is:

1. An apparatus for measuring an antenna radiation performance, comprising:
a chamber configured to include a transmit antenna radiating electromagnetic wave, a receive antenna receiving the electromagnetic wave, and an electromagnetic wave absorber absorbing the electromagnetic wave; and
a reflector disposed on one side of the chamber between the transmit antenna and the receive antenna, inclined at a predetermined angle, and configured to reflect an electromagnetic wave radiated in a direction to the one side from the transmit antenna.

2. The apparatus of claim 1, wherein the reflector is inclined at a predetermined angle toward the receive antenna.

3. The apparatus of claim 2, wherein the reflector reflects the electromagnetic wave in a direction parallel to the one side.

4. The apparatus of claim 1, wherein the reflector is inclined at a predetermined angle toward the transmit antenna.

5. The apparatus of claim 4, wherein the reflector reflects the electromagnetic wave in a direction parallel to the one side.

6. The apparatus of claim 1, further comprising:
a reflective plate formed in a parabola shape between the transmit antenna and an interior side of the chamber.

7. The apparatus of claim 1, wherein the reflector includes a first reflecting member inclined at a predetermined angle toward the receive antenna and a second reflecting member inclined at a predetermined angle toward the transmit antenna.

8. The apparatus of claim 7, wherein the first and second reflecting members reflect the electromagnetic wave in a direction parallel with the one side.

9. A method for designing an antenna radiation performance measuring apparatus including a chamber configured to have a transmit antenna radiating electromagnetic wave, a receive antenna receiving the electromagnetic wave, and an electromagnetic wave absorber absorbing the electromagnetic wave, and a reflector disposed on one side of the chamber between the transmit antenna and the receive antenna, inclined at a predetermined angle, and configured to reflect an electromagnetic wave radiated in a direction to the one side from the transmit antenna, the method comprising:
deciding parameters according to locations of the transmit antenna and the receive antenna in the chamber;
measuring an angle and a location of the reflector based on the decided parameters;
confirming performance of uniformity of electric field of an electromagnetic wave received at the receive antenna; and
measuring a radiation pattern and a gain of the receive antenna.

10. The method of claim 9, wherein said measuring an angle and a location of the reflector includes:
deciding a location of a reflective plate formed in a parabola shape between the transmit antenna and an interior side of the chamber.
